(19) United States
(12) Patent Application Publication
(10) Pub. No.: US 2024/0332173 A1
(43) Pub. Date: Oct. 3, 2024

(54) SEMICONDUCTOR DEVICE

(71) Applicant: FUJI ELECTRIC CO., LTD., Kanagawa (JP)

(72) Inventor: Tomoyuki OBATA, Matsumoto-city (JP)

(21) Appl. No.: 18/582,591

(22) Filed: Feb. 20, 2024

(30) Foreign Application Priority Data
Apr. 3, 2023 (JP) 2023-060220

(51) Int. Cl. H01L 23/528; H01L 29/739; H01L 29/861

(52) U.S. Cl. CPC H01L 23/528; H01L 29/7397; H01L 29/861

(57) ABSTRACT

There is provided a semiconductor device including an active portion which is provided in a semiconductor substrate; a temperature sensing portion which has a PN junction provided above the semiconductor substrate; an interlayer dielectric film provided above the semiconductor substrate; and a front surface side electrode provided above the interlayer dielectric film, in which a contact region between the front surface side electrode and the interlayer dielectric film covers the PN junction, in a top view. The semiconductor device may include a conductive wiring portion electrically connected to the temperature sensing portion, inside the interlayer dielectric film.

The contents of the following patent applications are incorporated herein by reference:
NO. 2023-060220 filed in JP on Apr. 3, 2023

### BACKGROUND

### 1. Technical Field

The present invention relates to a semiconductor device.

### 2. Related Art

Patent Document 1 discloses that “a triple point does not exist since the plated layer 36 is away from the protective film 150. Accordingly, the stress concentration due to the triple point can be prevented”.

### PRIOR ART DOCUMENT

Patent Document
Patent Document 1: Japanese Patent Application Publication No. 2022-178755

### BRIEF DESCRIPTION OF THE DRAWINGS

FIG. 1 shows an example of an arrangement of each component and a gate wiring portion at a front surface of a semiconductor device 100.

FIG. 2A shows an example of a top plan view of the semiconductor device 100.

FIG. 2B shows an example of a cross sectional view B-B′ of the semiconductor device 100.

FIG. 3A shows an enlarged view of a vicinity of a temperature sensing portion 178 in a cross sectional view A-A′ of the semiconductor device 100.

FIG. 3B shows an example of the cross sectional view A-A′ of the semiconductor device 100.

FIG. 4A shows an example of a cross sectional view a-a′ of the semiconductor device 100.

FIG. 4B shows a modification example of the cross sectional view a-a′ of the semiconductor device 100.

FIG. 4C shows an example of a cross sectional view b-b′ of the semiconductor device 100.

FIG. 4D shows an example of a cross sectional view c-c′ of the semiconductor device 100.

FIG. 5 shows an example of an upper surface of the semiconductor device 100.

### DESCRIPTION OF EXEMPLARY EMBODIMENTS

Hereinafter, embodiments of the present invention will be described. However, the following embodiments are not for limiting the invention according to the claims. In addition, not all of the combinations of features described in the embodiments are essential to the solution of the invention.

In the present specification, technical matters may be described using orthogonal coordinate axes consisting of an X axis, a Y axis, and a Z axis. The orthogonal coordinate axes merely specify relative positions of components, and do not limit a specific direction. For example, the Z axis is not limited to indicating a height direction with respect to the ground. It should be noted that a +Z axis direction and a −Z axis direction are directions opposite to each other. When the Z axis direction is described without describing the signs, it means that the direction is parallel to the +Z axis and the −Z axis. In addition, in the present specification, a view from the +Z axis direction may be referred to as a top view.

In the present specification, a case where a term such as “same” or “equal” is mentioned may include a case where an error due to a variation in manufacturing or the like is included. The error is, for example, within 10%.

In the present specification, a conductivity type of a doping region where doping has been carried out with an impurity is described as a P type or an N type. Note that the conductivity type of each doping region may also be of reversed polarity. In addition, in the present specification, a term p+ type or n+ type means that its doping concentration is higher than that of the p type or n type, and a term p-type or n-type means that its doping concentration is lower than that of the p type or n type.

The doping concentration in the present specification indicates a concentration of an impurity activated as a donor or an acceptor. In the present specification, in some cases, a concentration difference between the donor and the acceptor may be a higher concentration of the two, the donor or the acceptor. The concentration difference can be measured by capacitance-voltage profiling (CV profiling). Also, a carrier concentration measured by a spread resistance (SR) measurement method may be a concentration of the donor or the acceptor. In addition, in a case where a concentration distribution of the donor or the acceptor has a peak, the peak value may be a concentration of the donor or the acceptor in the region. In a region where donors or acceptors are present, when the concentration of the donors or the acceptors is substantially uniform or the like, an average value of the donor concentration or the acceptor concentration in this region may be set as the donor concentration or the acceptor concentration.

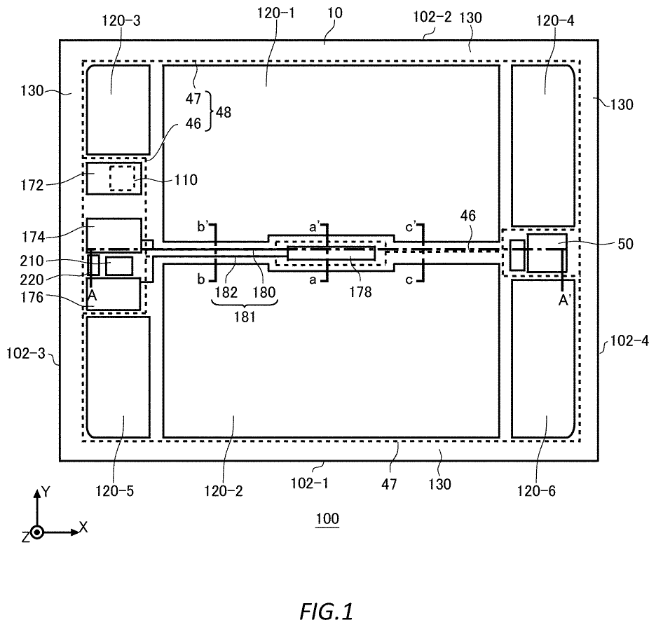

FIG. 1 shows an example of an upper surface of a semiconductor device 100. The semiconductor device 100 includes a semiconductor substrate 10, a gate pad 50, a current sensing pad 172, a temperature sensing portion 178, and an anode pad 174 and a cathode pad 176 which are electrically connected to the temperature sensing portion 178. The semiconductor device 100 may include a bidirectional diode portion 210 and an output comparison diode portion 220. A gate wiring portion 48 includes metal wiring 47 and a gate runner 46.

The semiconductor substrate 10 has an edge side 102. As used herein, in the top view of FIG. 1, a direction along one edge side 102-1 of the semiconductor substrate 10 is considered to be an X axis direction, and a direction perpendicular to the X axis direction is considered to be a Y axis direction. In the present example, the X axis is taken in a direction along the edge side 102-1. In addition, a direction being perpendicular to the X axis direction and the Y axis direction, and forming a right-hand system with the X axis direction and the Y axis direction is referred to as a Z axis direction.

The semiconductor substrate 10 has an active portion 120 at a front surface. The active portion 120 is a region in which a main current flows in a depth direction between the front surface and a back surface of the semiconductor substrate 10 when the semiconductor device 100 is turned on. A gate conductive portion 44 which will be described below is electrically connected to the gate pad 50 by the gate wiring portion 48.

The active portion 120 may include an active portion 120-1, an active portion 120-2, an active portion 120-3, an active portion 120-4, an active portion 120-5, and an active portion 120-6, which are divided and arranged. The active portion 120 may be provided with a transistor portion 70 including a transistor element such as an IGBT (insulated gate bipolar transistor) and a MOS-FET (metal oxide semiconductor field effect transistor), and may be provided with a diode portion 80 including a diode element such as a FWD (freewheeling diode). The transistor portion 70 and the diode portion 80 will be described below. The active portion 120 may be a region in which at least one of the transistor portion 70 or the diode portion 80 is provided. The transistor portion 70 and the diode portion 80 may be alternately arranged in each region in the active portion 120 along the X axis direction.

The semiconductor device 100 has a well region 130 of the P+ type outside the active portion 120 at the front surface. The semiconductor device 100 has an edge termination structure portion outside the well region 130. The edge termination structure portion includes, for example, a guard ring that is annularly provided so as to surround the active portion 120, or a field plate, or a combination thereof.

The temperature sensing portion 178 is provided above the semiconductor substrate 10. The temperature sensing portion 178 in the present example is provided near the center of the semiconductor substrate 10. When the active portions 120 of the semiconductor substrate 10 are integrated, the center of the semiconductor substrate 10 is easily heated by heat generated from switching devices which are formed in the active portions 120. By providing the temperature sensing portion 178 near the center, a temperature of the transistor portion 70 can be monitored. This can prevent the transistor portion 70 from overheating beyond a junction temperature that is a normal operating temperature range.

The temperature sensing portion 178 may have a PN junction. The temperature sensing portion 178 may include a temperature sensing diode. As an example, the temperature sensing portion 178 is provided by a Schottky diode. In addition, the temperature sensing portion 178 may include a PN junction diode that is provided above the semiconductor substrate 10 via a dielectric film, and is made of polycrystalline silicon. The temperature sensing portion 178 may include a temperature resistor whose resistance value is temperature dependent. For example, polycrystalline silicon may be used as the temperature resistor.

A conductive wiring portion 181 connects the temperature sensing portion 178, and the anode pad 174 and the cathode pad 176. The conductive wiring portion 181 is provided extending in a predetermined direction (in the present example, the X axis direction) inside an interlayer dielectric film 380 which will be described below. The conductive wiring portion 181 includes first wiring 180 and second wiring 182.

The conductive wiring portion 181 may be made of polysilicon. The conductive wiring portion 181 may be made of metal with a high melting point such as tungsten, titanium, titanium nitride, tantalum, and tantalum nitride. By the conductive wiring portion 181 being made of polysilicon or metal with a high melting point, it is possible to suppress a deterioration of temperature sensing wiring due to migration.

The first wiring 180 connects one end of the temperature sensing portion 178 and the anode pad 174. The first wiring 180 in the present example extends inside the interlayer dielectric film 380 provided above the semiconductor substrate 10, and is not provided above the interlayer dielectric film 380. In this way, by forming the first wiring 180 inside the interlayer dielectric film 380, it is possible to connect the temperature sensing portion 178 and the anode pad 174, without providing a protective film such as a polyimide film above the conductive wiring portion 181 and the temperature sensing portion 178.

The second wiring 182 connects another end of the temperature sensing portion 178 and the cathode pad 176. The second wiring 182 may be formed simultaneously with the first wiring 180, or may be formed separately. A material of the second wiring 182 may be the same as or different from a material of the first wiring 180.

Similarly to the first wiring 180, the second wiring 182 in the present example extends inside the interlayer dielectric film 380 provided above the semiconductor substrate 10, and is not provided above the interlayer dielectric film 380. In this way, by forming the second wiring 182 inside the interlayer dielectric film 380, it is possible to connect the temperature sensing portion 178 and the cathode pad 176, without providing a protective film such as a polyimide film above the conductive wiring portion 181 and the temperature sensing portion 178.

The cathode pad 176 is connected to the temperature sensing portion 178 via the second wiring 182. The anode pad 174 is connected to the temperature sensing portion 178 via the first wiring 180. The cathode pad 176 and the anode pad 174 are electrodes containing metal such as aluminum.

The current sensing pad 172 is electrically connected to a current sensing portion 110. The current sensing pad 172 is an example of a front surface side electrode. The current sensing portion 110 has a structure similar to the structure of the transistor portion 70 in the active portion 120, and simulates operations of the transistor portion 70. A current that flows into the current sensing portion 110 is in proportion to a current that flows into the transistor portion 70. This makes it possible to monitor a current flow of the transistor portion 70.

It should be noted that the current sensing portion 110 is different from the transistor portion 70 in that the current sensing portion 110 has no emitter region 12, which will be described below. In this manner, the current sensing portion 110 does not operate as a transistor. The current sensing portion 110 is provided with a gate trench portion. The gate trench portion of the current sensing portion 110 is electrically connected to a gate wiring portion.

The bidirectional diode portion 210 is arranged between the anode pad 174 and the cathode pad 176 at the front surface of the semiconductor device 100. The bidirectional diode portion 210 includes a diode electrically connected in a serial bidirectional way between the anode pad 174 and the cathode pad 176. The bidirectional diode portion 210 prevents the temperature sensing portion 178 from being damaged by an Electro-Static Discharge (ESD).

The output comparison diode portion 220 is provided between the anode pad 174 and the cathode pad 176. The output comparison diode portion 220 is electrically connected to the anode pad 174 and the cathode pad 176. The output comparison diode portion 220 includes an output comparison diode having a direction of the PN junction connected antiparallel to a direction of the PN junction of the temperature sensing portion 178.

At a time of an operation of the semiconductor device 100, no current is applied to the output comparison diode portion 220. An output comparison operation is performed for each predetermined cycle. At a time of the output comparison operation, the current is applied to the output comparison diode portion 220. By the output comparison operation, it is possible to grasp a time for replacing the temperature sensing portion 178.

The gate wiring portion 48 may be electrically connected to the gate pad 50. Further, the gate wiring portion 48 is connected to the below-described gate conductive portion 44 of the transistor portion 70 arranged in the active portion 120, and sets the gate conductive portion 44 to a gate potential. The gate conductive portion 44 corresponds to a gate electrode of the transistor portion 70. In this manner, a transistor of the transistor portion 70 is switched on.

The metal wiring 47 is provided above the semiconductor substrate 10. The metal wiring 47 may extend in an annular shape to surround an outer periphery of the active portion 120. The metal wiring 47 may be formed of a conductive material such as aluminum or an aluminum-silicon alloy. The metal wiring 47 and an emitter electrode 52 are provided separately from each other.

The gate runner 46 is provided above the semiconductor substrate 10 and below the metal wiring 47. The gate runner 46 is electrically connected to the metal wiring 47. The gate runner 46 may extend in an annular shape to surround the outer periphery of the active portion 120, and may be arranged to surround the temperature sensing portion 178. The gate runner 46 may be formed to partially overlap the conductive wiring portion 181 in the top view. The gate runner 46 may be formed to partially overlap the temperature sensing portion 178 in the top view.

The gate runner 46 may be formed of the same material as that of the metal wiring 47, or may be formed of a different material. The gate runner 46 in the present example is made of polysilicon.

In FIG. 1, a position where the gate wiring portion 48 is provided at the front surface of the semiconductor substrate 10 is indicated by a dashed line. Note that the position of the wiring in the drawing merely shows an approximate position to avoid a confusion with other wiring. The detailed position of the gate wiring portion 48 will be described below.

The gate pad 50 is electrically connected to an external control terminal. The gate pad 50 is formed of a conductor made of metal such as aluminum. The gate pad 50 may be externally connected by means of wire bonding.

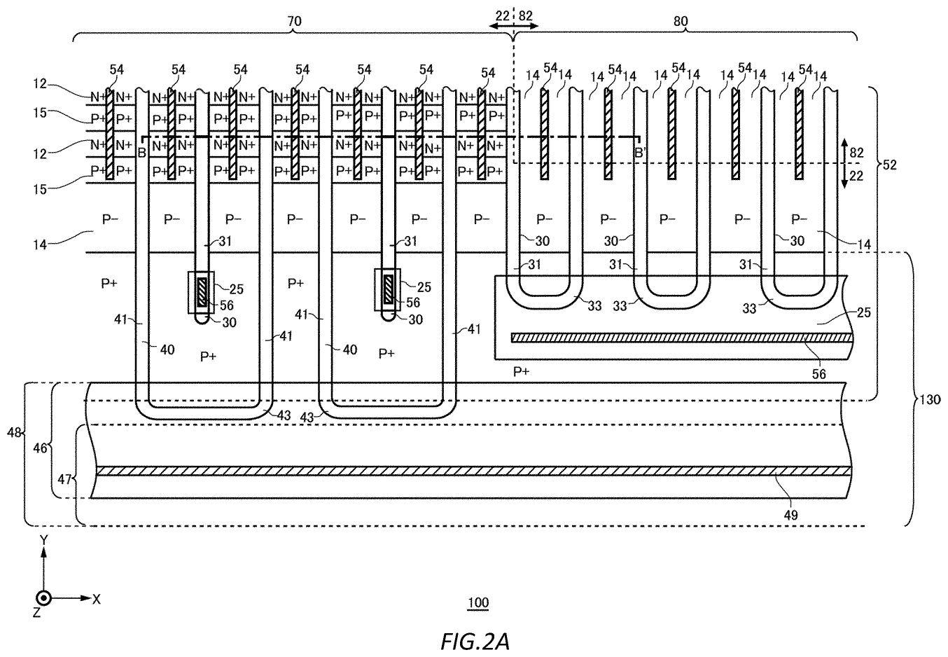

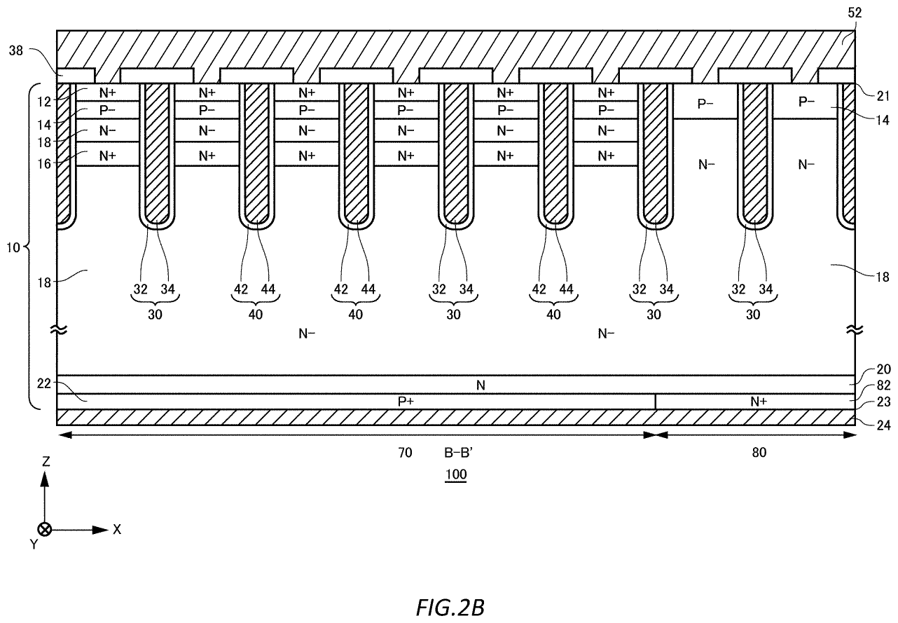

FIG. 2A is an example of a top plan view of the semiconductor device 100. FIG. 2A shows a vicinity of an end portion of the active portion 120-2 on a negative side in the Y axis direction. The semiconductor device 100 includes the semiconductor substrate 10 having the transistor portion 70 including a transistor element such as an IGBT, and the diode portion 80 including a diode element such as a freewheeling diode (FWD).

The semiconductor device 100 of the present example includes a gate trench portion 40, a dummy trench portion 30, the well region 130, the emitter region 12, a base region 14, and a contact region 15 which are provided inside a front surface side of the semiconductor substrate 10. The gate trench portion 40 and the dummy trench portion 30 each are an example of the trench portion.

In addition, the semiconductor device 100 of the present example includes the metal wiring 47 and the emitter electrode 52 which are provided above the front surface of the semiconductor substrate 10. The emitter electrode 52 is an example of the front surface side electrode. The metal wiring 47 and the emitter electrode 52 are electrically insulated.

An interlayer dielectric film is provided between the emitter electrode 52 and the metal wiring 47, and the front surface of the semiconductor substrate 10, although it is omitted in FIG. 2A. In the interlayer dielectric film of the present example, contact holes 49, 54 and 56 are provided penetrating through the interlayer dielectric film. In FIG. 2A, each contact hole is hatched with oblique lines.

The emitter electrode 52 is provided above the gate trench portion 40, the dummy trench portion 30, the well region 130, the emitter region 12, the base region 14, and the contact region 15. The emitter electrode 52 is electrically connected to the emitter region 12, the base region 14, and the contact region 15 at the front surface of the semiconductor substrate 10, by the contact hole 54.

In addition, the emitter electrode 52 is connected to a dummy conductive portion in the dummy trench portion 30 by the contact hole 56. A connection portion 25 formed of a conductive material such as polysilicon doped with impurities may be provided between the emitter electrode 52 and the dummy conductive portion. The connection portion 25 is provided at the front surface of the semiconductor substrate 10 via a dielectric film such as the interlayer dielectric film and a dummy dielectric film of the dummy trench portion 30.

The gate runner 46 is connected to the gate conductive portion in the gate trench portion 40 at the front surface of the semiconductor substrate 10. The gate runner 46 is electrically connected to the metal wiring 47 via the contact hole 49. The gate runner 46 is not electrically connected to the dummy conductive portion in the dummy trench portion 30 and the emitter electrode 52.

The gate runner 46 and the emitter electrode 52 are electrically separated by an insulator such as the interlayer dielectric film and an oxide film. The gate runner 46 of the present example is provided from a position below the contact hole 49 to an edge portion (an end portion in the Y axis direction) of the gate trench portion 40. At the edge portion of the gate trench portion 40, the gate conductive portion is exposed to the front surface of the semiconductor substrate 10, and is connected to the gate runner 46.

The emitter electrode 52 is formed of a conductive material including metal. For example, they are formed of aluminum or an aluminum-silicon alloy. The emitter electrode 52 may have barrier metal formed of titanium, a titanium compound, and the like under a region formed of aluminum and the like.

The emitter electrode 52 may also have a plug formed of tungsten or the like in the contact hole. The plug may have the barrier metal on a side in contact with the semiconductor substrate 10 and have tungsten embedded to be in contact with the barrier metal, and may be formed of aluminum or the like on tungsten.

The well region 130 extends to an outside of the gate runner 46 to overlap an outer peripheral region, and is annularly provided in the top view. The well region 130 also extends to the active portion 120 inside the gate runner 46 by a predetermined width, and is annularly provided in the top view. The well region 130 in the present example is provided in a range farther away from an end portion of the contact hole 54 in the Y axis direction toward a gate runner 46 side. The well region 130 is a region of a second conductivity type in which the doping concentration is higher than that of the base region 14. The doping concentration of the well region 130 may be the same as the doping concentration of the contact region 15, or may be lower than that. The gate runner 46 is electrically insulated from the well region 130.

The base region 14 of the present example is the P− type, and the well region 130 is the P+ type. In addition, the well region 130 is formed from the front surface of the semiconductor substrate to a position deeper than a lower end of the base region 14. The base region 14 is provided in contact with the well region 130 in the transistor portion 70 and the diode portion 80. The well region 130 is electrically connected to the emitter electrode 52.

Each of the transistor portion 70 and the diode portion 80 includes a plurality of trench portions arrayed in an array direction. In the transistor portion 70 of the present example, one or more gate trench portions 40 and one or more dummy trench portions 30 are alternately provided along the array direction. In the diode portion 80 of the present example, the plurality of dummy trench portions 30 is provided along the array direction.

In the present example, the array direction of the trench portions is the X axis direction, and the extension direction perpendicular to the array direction is the Y axis direction. The gate trench portion 40 of the present example may have two extension parts 41 extending along the extension direction (parts of the trench that are linear along the extension direction), and a connection part 43 connecting the two extension parts 41.

At least a part of the connection part 43 may be provided in a curved shape in the top view. The connection part 43 connects end portions of the two extension parts 41 in the Y axis direction to the gate runner 46, which functions as a gate electrode to the gate trench portion 40. On the other hand, by forming the connection part 43 into the curved shape, an electric field concentration at the end portions can be reduced, in comparison with a case where the extension part 41 makes the completion.

In the transistor portion 70, the dummy trench portions 30 are provided between the respective extension parts 41 of the gate trench portions 40. In the example of FIG. 2A, one dummy trench portion 30 is provided between the respective extension parts 41; however, two or more dummy trench portions 30 may be provided.

In addition, between the respective extension parts 41, the dummy trench portion 30 may not be provided, and the gate trench portion 40 may be provided. with such a structure, the electron current from the emitter region 12 can be increased, so that an ON voltage is reduced.

The dummy trench portion 30 may have a linear shape extending in the extension direction, and may have an extension part 31 and a connection part 33, similarly to the gate trench portion 40. In the semiconductor device 100 shown in FIG. 2A, only the dummy trench portion 30 having the connection part 33 is arrayed; however, in another example, the semiconductor device 100 may include the dummy trench portion 30 with a linear shape that does not have the connection part 33.

A diffusion depth of the well region 130 may be deeper than depths of the gate trench portion 40 and the dummy trench portion 30. The end portions in the Y axis direction of the gate trench portion 40 and the dummy trench portion 30 are provided in the well region 130 in the top view. That is, at the end portion of each trench portion in the Y axis direction, a bottom portion of each trench portion in the depth direction (a positive side in the Z axis direction) is covered with the well region 130. With this configuration, the electric field concentration on the bottom portion of each trench portion can be reduced.

A mesa portion is provided between the respective trench portions in the array direction. The mesa portion refers to a region sandwiched between the trench portions inside the semiconductor substrate 10. As an example, a depth position of the mesa portion is from the front surface of the semiconductor substrate to a lower end of the trench portion.

The mesa portion of the present example is sandwiched between trench portions that are adjacent to each other in the X axis direction, and is provided to extend in the extension direction (the Y axis direction) along the trench at the front surface of the semiconductor substrate 10.

Each mesa portion is provided with the base region 14. In each mesa portion, at least one of the emitter region 12 of a first conductivity type or the contact region 15 of the second conductivity type may be provided in a region sandwiched between the base regions 14 in the top view. The emitter region 12 of the present example is the N+ type, and the contact region 15 is the P+ type. The emitter region 12 and the contact region 15 may be provided between the base region 14 and the front surface of the semiconductor substrate 10 in the depth direction. Examples of a dopant of the emitter region 12 include arsenic (As), phosphorus (P), antimony (Sb), and the like.

The mesa portion of the transistor portion 70 has the emitter region 12 exposed to the front surface of the semiconductor substrate 10. The emitter region 12 is provided in contact with the gate trench portion 40. The mesa portion in contact with the gate trench portion 40 is provided with the contact region 15 exposed to the front surface of the semiconductor substrate 10.

Each of the contact region 15 and the emitter region 12 in the mesa portion is provided from one trench portion to the other trench portion in the X axis direction. As an example, the contact region 15 and the emitter region 12 in the mesa portion are alternately arranged along the extension direction of the trench portion (the Y axis direction).

In another example, the contact region 15 and the emitter region 12 in the mesa portion may be provided in a stripe shape along the extension direction of the trench portion (the Y axis direction). For example, the emitter region 12 is provided in a region in contact with the trench portion, and the contact region 15 is provided in a region sandwiched between the emitter regions 12.

The mesa portion of the diode portion 80 is not provided with the emitter region 12. An upper surface of the mesa portion of the diode portion 80 may be provided with the base region 14. The base region 14 may be arranged in the entire mesa portion of the diode portion 80. The base region 14 of the diode portion 80 operates as an anode.

The contact hole 54 is provided above each mesa portion. The contact hole 54 is arranged in a region sandwiched between the base regions 14 in its extension direction (the Y axis direction). The contact hole 54 of the present example is provided above each region of the contact region 15, the base region 14, and the emitter region 12. The contact hole 54 may be arranged at the center of the mesa portion in the array direction (the X axis direction).

In the diode portion 80, a region adjacent to the back surface of the semiconductor substrate is provided with a cathode region 82 of the N+ type. In the back surface of the semiconductor substrate, a region in which the cathode region 82 is not provided may be provided with a collector region 22 of the P+ type. In FIG. 2A, a boundary between the cathode region 82 and the collector region 22 is indicated by a dotted line.

The boundary between the collector region 22 and the cathode region 82 is a boundary between the transistor portion 70 and the diode portion 80. That is, in the present example, the transistor portion 70 is a region where the collector region 22 provided in a back surface side of the semiconductor substrate 10 is projected onto an upper surface of the semiconductor substrate 10. In addition, the diode portion 80 is a region where the cathode region 82 provided at the back surface of the semiconductor substrate 10 is projected onto the upper surface of the semiconductor substrate 10.

FIG. 2B shows an example of a cross section B-B′ in FIG. 2A. The cross section B-B′ is an XZ plane passing through the emitter region 12 in the transistor portion 70. The semiconductor device 100 of the present example has: the semiconductor substrate 10 including the emitter region 12, the base region 14, an accumulation region 16, a drift region 18, a buffer region 20, the collector region 22, and the cathode region 82; an interlayer dielectric film 38; and the emitter electrode 52 and a collector electrode 24, in the cross section B-B′. The collector electrode 24 is an example of a back surface side metal layer provided in contact with a back surface 23 of the semiconductor substrate 10.

The drift region 18 is a region of the first conductivity type which is provided in the semiconductor substrate 10. The drift region 18 in the present example is the N-type as an example. The drift region 18 may be a region that has remained without other doping regions being formed in the semiconductor substrate 10. That is, the doping concentration of the drift region 18 may be the doping concentration of the semiconductor substrate 10.

The accumulation region 16 is a region of the first conductivity type provided below the base region 14 in the semiconductor substrate 10. The doping concentration of the accumulation region 16 is higher than the doping concentration of the drift region 18. the accumulation region 16 in the present example is the N+ type as an example.

The accumulation region 16 may be provided in the transistor portion 70, and may not provided in the diode portion 80. The accumulation region 16 may be provided in both of the transistor portion 70 and the diode portion 80. By providing the accumulation region 16, it is possible to enhance the carrier injection enhancement effect (IE EFFECT) to reduce an ON voltage of the transistor portion 70.

The buffer region 20 of the first conductivity type may be provided below the drift region 18. The buffer region 20 of the present example is the n type. The doping concentration of the buffer region 20 is higher than the doping concentration of the drift region 18. The buffer region 20 may function as a field stopper layer configured to prevent a depletion layer expanding from a lower surface side of the base region 14 from reaching the collector region 22 and the cathode region 82.

In the transistor portion 70, the collector region 22 is provided below the buffer region 20. The collector region 22 may be provided in contact with the cathode region 82 in the back surface 23.

In the diode portion 80, the cathode region 82 is provided below the buffer region 20. The cathode region 82 may be provided at the same depth as that of the collector region 22 of the transistor portion 70. The diode portion 80 may function as a freewheeling diode (FWD) configured to pass a freewheeling current that is conducted in a reverse direction, when the transistor portion 70 is turned off.

The collector electrode 24 is formed at the back surface 23 of the semiconductor substrate 10. The collector electrode 24 is formed of a conductive material such as metal. The collector electrode 24 may be formed of the same conductive material as that of the emitter electrode 52, or may be formed of a different conductive material.

The gate trench portion 40 has a gate trench, a gate dielectric film 42, and the gate conductive portion 44 which are formed at a front surface 21. The gate dielectric film 42 is formed to cover an inner wall of the gate trench. The gate dielectric film 42 may be formed by oxidizing or nitriding a semiconductor on the inner wall of the gate trench. The gate conductive portion 44 is formed in an interior of the gate trench, and is also formed inside the gate dielectric film 42. The gate dielectric film 42 insulates the gate conductive portion 44 from the semiconductor substrate 10. The gate conductive portion 44 is formed of a conductive material such as polysilicon. The gate trench portion 40 is covered with the interlayer dielectric film 38 at the front surface 21.

The gate conductive portion 44 includes a region facing the base region 14 which is adjacent with the gate dielectric film 42 being sandwiched therebetween in the depth direction of the semiconductor substrate 10. When a predetermined voltage is applied to the gate conductive portion 44, a channel is formed to a surface layer being at a boundary within the base region 14 and in contact with the gate trench, due to an electron inversion layer.

The dummy trench portion 30 may have the same structure as that of the gate trench portion 40. The dummy trench portion 30 includes a dummy trench, a dummy dielectric film 32, and a dummy conductive portion 34 which are formed in a front surface 21 side. The dummy dielectric film 32 is formed to cover an inner wall of the dummy trench. The dummy conductive portion 34 is formed in an interior of the dummy trench, and is also formed inside the dummy dielectric film 32. The dummy dielectric film 32 insulates the dummy conductive portion 34 from the semiconductor substrate 10. The dummy trench portion 30 is covered with the interlayer dielectric film 38 at the front surface 21.

The interlayer dielectric film 38 is provided on the front surface 21. The emitter electrode 52 is provided above the interlayer dielectric film 38. The interlayer dielectric film 38 may be provided with one or more trench contact portions to electrically connect the emitter electrode 52 and the semiconductor substrate 10. Similarly, the contact hole 49 and the contact hole 56 may also have the trench contact portion provided to pass through the interlayer dielectric film 38.

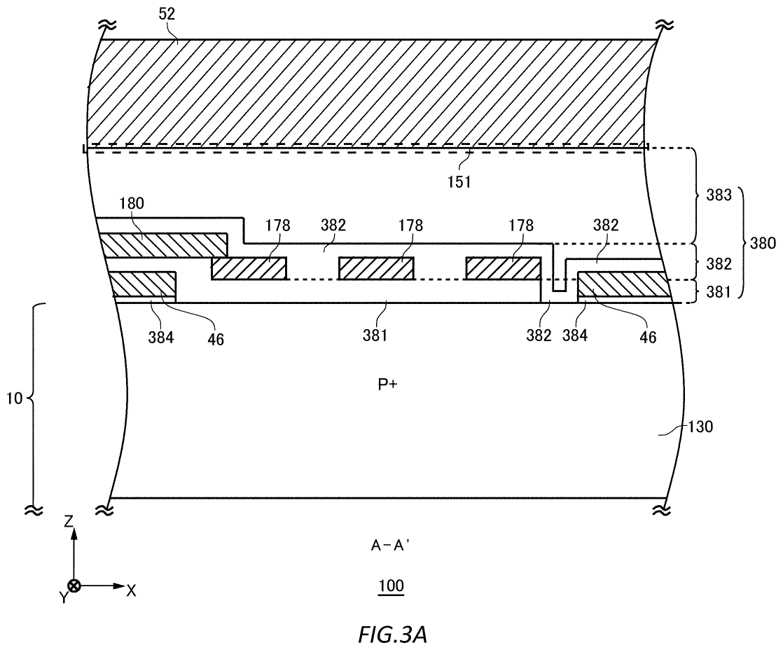

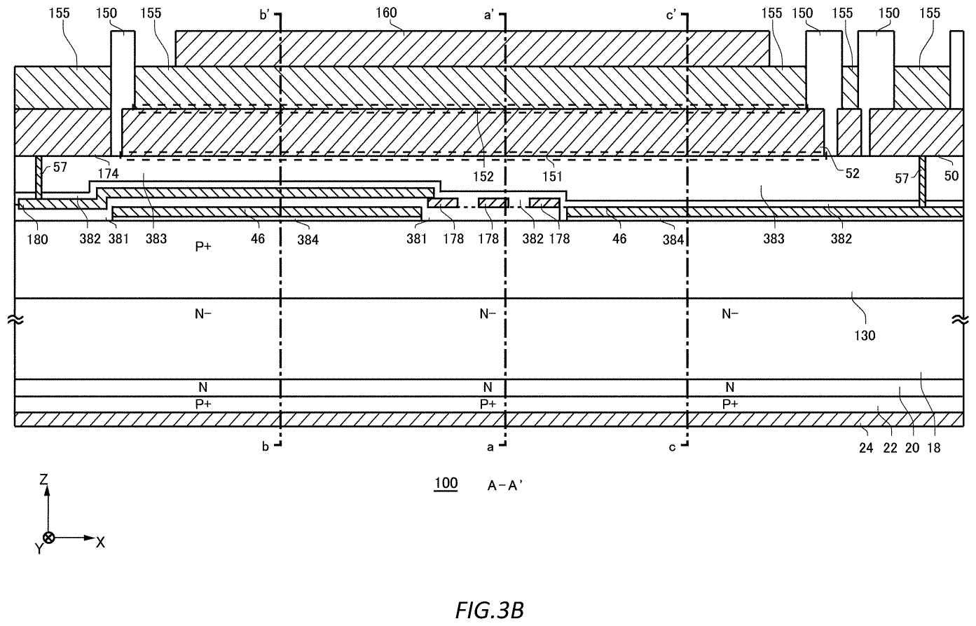

FIG. 3A is a view showing an example of an enlarged view of a vicinity of the temperature sensing portion 178 in a cross section A-A′ of FIG. 1. The cross section A-A′ is an XZ cross section passing through the anode pad 174, the gate runner 46, the first wiring 180, the temperature sensing portion 178, and the gate pad 50.

The interlayer dielectric film 380 is provided between the front surface of the semiconductor substrate 10 and the front surface side electrode. The interlayer dielectric film 380 includes a first dielectric layer 381, a second dielectric layer 382, a third dielectric layer 383, and a gate oxide film 384. The interlayer dielectric film 380 may include an additional dielectric layer.

The gate oxide film 384 is provided between the gate runner 46 and the semiconductor substrate 10. Similarly to the dummy dielectric film 32 and the gate dielectric film 42, the gate oxide film 384 may be formed by oxidizing or nitriding the front surface of the semiconductor substrate 10.

The first dielectric layer 381 is provided above the front surface of the semiconductor substrate 10. The first dielectric layer 381 may be provided on lower surfaces of the temperature sensing portion 178 and the conductive wiring portion 181. The first dielectric layer 381 may be a high temperature silicon oxide (HTO: High Temperature Oxide) film. The first dielectric layer 381 may be a silicon oxide film which is non-doped. In an example, the first dielectric layer 381 is formed of silicon oxide (SiO₂). By providing the first dielectric layer 381 on the lower surface of the temperature sensing portion 178, it is possible to enhance a breakdown voltage.

The second dielectric layer 382 is provided above the first dielectric layer 381. The second dielectric layer 382 may be provided on an upper surface of the conductive wiring portion 181. The material of the second dielectric layer 382 may be the same as or different from that of the first dielectric layer 381.

In the present example, both of the first dielectric layer 381 and the second dielectric layer 382 are the silicon oxide films which are non-doped. By the first dielectric layer 381 and the second dielectric layer 382 being made of the silicon oxide films which are non-doped, even when the gate runner 46, the temperature sensing portion 178, and the conductive wiring portion 181 are made of polysilicon, it is possible to prevent a contamination by an element such as boron (B) that is contained in the interlayer dielectric film 38.

The third dielectric layer 383 is provided above the second dielectric layer 382. The third dielectric layer 383 may be a BPSG (Boro-phospho Silicate Glass) film, may be a BSG (borosilicate glass) film, or may be a PSG (Phosphosilicate glass) film. The third dielectric layer 383 in the present example is the BPSG film.

The temperature sensing portion 178 may be made of polysilicon. The temperature sensing portion 178 of the present example has the PN junction in the Y axis direction. A resistance of the PN junction exhibits temperature dependence, and thus it is possible for the temperature sensing portion 178 to measure the temperature in the active portion 120 of the semiconductor device 100.

The PN junction of the temperature sensing portion 178 is covered with the interlayer dielectric film 380 and a contact region 151 of the front surface side electrode in the top view. In the semiconductor device of a comparison example, anode wiring or cathode wiring connected to the temperature sensing portion 178 is provided above the temperature sensing portion 178, and the front surface side electrode is not provided. In the semiconductor device 100 of the present example, the anode wiring and the cathode wiring are not provided above the temperature sensing portion 178, and the temperature sensing portion 178 is electrically connected by the conductive wiring portion 181 extending inside the interlayer dielectric film 380, and thus it is possible to cover the PN junction with the contact region 151.

An upper surface of the temperature sensing portion 178 is covered with the second dielectric layer 382. In the semiconductor device of the comparison example, a contact hole for connecting the temperature sensing portion 178 and the anode wiring or the cathode wiring is provided above the temperature sensing portion 178, and is not covered with the second dielectric layer 382. In the semiconductor device 100 of the present example, by providing the conductive wiring portion 181 inside the interlayer dielectric film 380, it is possible to cover the upper surface of the temperature sensing portion 178 with the second dielectric layer 382, and to stabilize a characteristic of the temperature sensing portion 178.

FIG. 3B shows an example of a cross section A-A′ in FIG. 1. In FIG. 3B, hatching is shown in a part that is conductive.

As shown in FIG. 3B, the gate runner 46 may be provided to at least partially overlap the conductive wiring portion 181 in the top view. The gate runner 46 may be provided below the conductive wiring portion 181 with the interlayer dielectric film 380 being sandwiched between the gate runner 46 and the conductive wiring portion 181. The gate oxide film 384 may be provided between the gate runner 46 and the front surface of the semiconductor substrate 10. The gate runner 46 may be connected to the gate pad 50 via a contact hole 57.

As shown in FIG. 3B, the first wiring 180 is provided to extend inside the interlayer dielectric film 380 in the X axis direction. The first wiring 180 is connected to the anode pad 174 via the contact hole 57. This makes it possible to electrically connect the anode pad 174 and the temperature sensing portion 178. Similarly, the second wiring 182 can electrically connect the cathode pad 176 and the temperature sensing portion 178.

A plating film 155 is provided above the front surface side electrode. The plating film 155 is provided in a part that is above the front surface side electrode and in which a protective film 150 is not provided. The material of the plating film 155 may be metal having a higher surface tension than that of solder. In an example, the plating film 155 is for nickel plating.

A thickness of the plating film 155 may be thinner than a thickness of the front surface side electrode. The thickness of the plating film 155 may be 1.0 μm or more, and may be 6.0 μm or less.

In the top view, a contact region 152 between the plating film 155 and the front surface side electrode may cover the temperature sensing portion 178. In the semiconductor device of the comparison example, the anode wiring or the cathode wiring is provided above the temperature sensing portion, and the front surface side electrode and the plating film 155 are not provided.

A solder layer 160 is provided on an upper surface of the plating film 155. The solder layer 160 is electrically connected to an external control terminal. The solder layer 160 may form a lead frame region that is externally connected by a lead frame.

The protective film 150 is provided above the front surface side electrode. The protective film 150 may be in contact with an upper surface of the emitter electrode 52. By providing the protective film 150, it is possible to protect the upper surface of the semiconductor device 100. The protective film 150 is, as an example, a polyimide film.

The protective film 150 of the present example is provided to be spaced apart from the solder layer 160. Typically, the protective film 150 made of an organic material has a coefficient of thermal expansion different from those of the plating film 155 and the solder layer 160 which are made of the metal materials, and thus when there is a triple point where total three of the protective film 150, the plating film 155, and the solder layer 160 are in contact, a stress concentration may occur at the triple point. The protective film 150 of the present example is provided to be spaced apart from the solder layer 160, and thus it is possible to avoid the occurrence of the triple point, and to prevent the stress concentration from occurring.

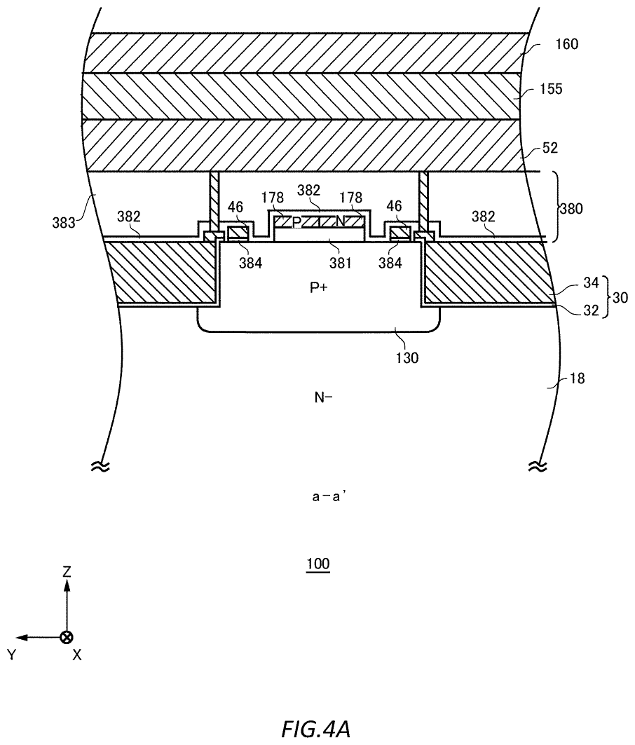

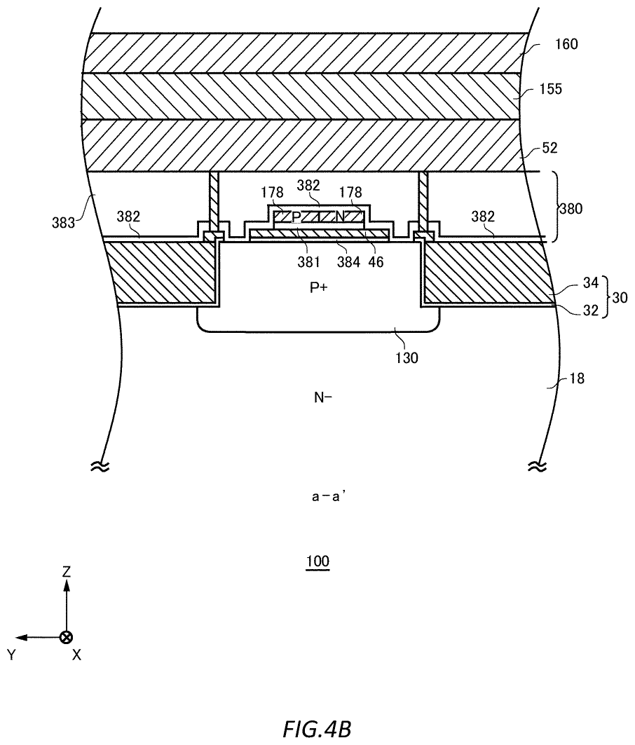

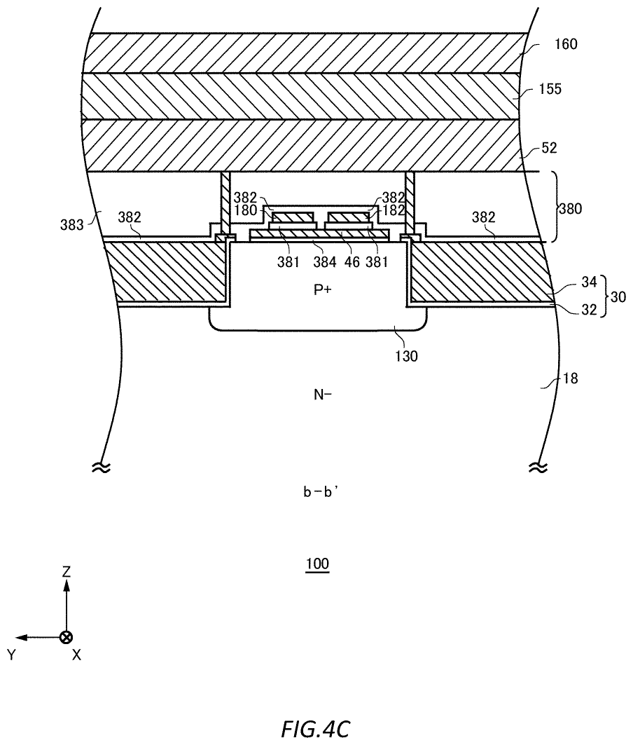

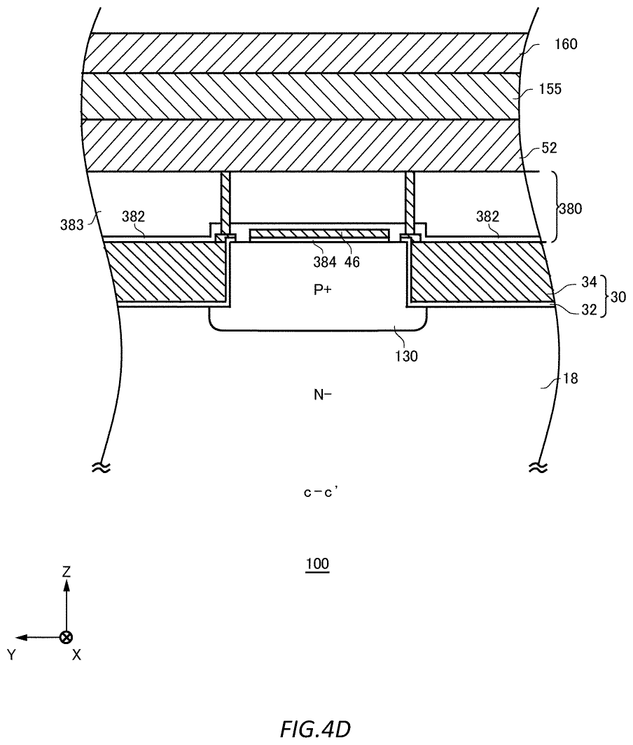

FIG. 4A shows an example of a cross section taken along lines a-a′ shown in FIG. 1 and FIG. 3B. The cross section taken along the lines a-a′ is a YZ cross section passing through the temperature sensing portion 178. The temperature sensing portion 178 of the present example has the PN junction in the XZ plane, but is not limited to this. That is, the temperature sensing portion 178 may have the PN junction in a different direction.

As an example, the temperature sensing portion 178 includes one semiconductor region of the first conductivity type and one semiconductor region of the second conductivity type. The temperature sensing portion 178 may include a plurality of semiconductor regions of the first conductivity type and a plurality of semiconductor regions of the second conductivity type. As an example, the temperature sensing portion 178 has a junction of a PNP type.

The temperature sensing portion 178 may not have the PN junction as long as temperature sensing portion 178 is made of polysilicon. A resistance value of polysilicon shows the temperature dependence, and thus it is possible for the temperature sensing portion 178 to measure the temperature of the semiconductor device 100. The resistance value in the temperature sensing portion 178 is higher when the temperature sensing portion 178 has the PN junction, than when the temperature sensing portion 178 does not have the PN junction, and thus it is possible to further enhance a precision of the temperature measurement.

In the present example, the anode pad 174 and a P type region of the temperature sensing portion 178 are connected, and the cathode pad 176 and an N type region of the temperature sensing portion 178 are connected, respectively. The anode pad 174 and the N type region of the temperature sensing portion 178 may be connected, and the cathode pad 176 and the P type region of the temperature sensing portion 178 may be connected, respectively. In this manner, when the temperature sensing portion 178 detects the temperature, the direction of the current flowing through the PN junction is reversed, and the resistance value at the PN junction of the temperature sensing portion 178 becomes high, and thus it is possible to enhance a precision of the temperature sensing portion 178.

FIG. 4B shows a modification example of the cross section taken along the lines a-a′ in FIG. 1 and FIG. 3B. In FIG. 4B, a difference from FIG. 4A will be described.

As shown in FIG. 4B, the gate runner 46 may be provided to partially overlap the temperature sensing portion 178 in the top view. That is, the temperature sensing portion 178 may be provided to face the gate runner 46 with the first dielectric layer 381 being sandwiched therebetween. The temperature sensing portion 178 may be provided above the gate runner 46. In an example, both of the P type region and the N type region included in the temperature sensing portion 178 are provided above the gate runner 46. In this way, by providing the interlayer dielectric film 380 between the gate runner 46 and the temperature sensing portion 178, it is possible to enhance a degree of freedom of each wiring inside the interlayer dielectric film 380.

FIG. 4C shows an example of a cross section taken along lines b-b′ shown in FIG. 1 and FIG. 3B. The cross section taken along the lines b-b′ is a YZ cross section passing between temperature sensing portion 178 and the anode pad 174. The semiconductor device 100 of the present example may have a structure in which the gate oxide film 384, the gate runner 46, the first dielectric layer 381, the conductive wiring portion 181, the second dielectric layer 382, and the third dielectric layer 383 are stacked in order, above the front surface of the semiconductor substrate 10.

The entire peripheries of the cross sections of the first wiring 180 and the second wiring 182 are covered with the interlayer dielectric film 380 which is non-doped. That is, the entire periphery of the conductive wiring portion 181 in a cross section perpendicular to the extension direction is covered with the first dielectric layer 381 and the second dielectric layer 382. In this way, by covering the conductive wiring portion 181 with the interlayer dielectric film 380 which is non-doped, it is possible to protect the conductive wiring portion 181 from the contamination, and stabilize the characteristic of the temperature sensing portion 178.

The conductive wiring portion 181 may be made of polysilicon, or may be made of a metal material with a high melting point. When the conductive wiring portion 181 is made of polysilicon, amounts of dopants that are contained in the conductive wiring portion 181 and the temperature sensing portion 178 may be the same as or different from each other. The resistance value of the conductive wiring portion 181 is lower when the conductive wiring portion 181 is made of the metal material, than when the conductive wiring portion 181 is made of polysilicon, and thus it is possible to enhance a precision of the temperature detection of the temperature sensing portion 178.

The cross sectional area of the conductive wiring portion 181 is greater than that of the PN junction of the temperature sensing portion 178. That is, in the present example, the cross sectional area (an area) of the PN junction of the temperature sensing portion 178 in the XZ plane is smaller than the cross sectional area of the conductive wiring portion 181 in an YZ plane. In this manner, the resistance value at the PN junction of the temperature sensing portion 178 becomes higher than the resistance value of the conductive wiring portion 181, and even when the conductive wiring portion 181 is made of polysilicon, it is possible to enhance a precision of the temperature sensing portion 178.

The gate runner 46 and the conductive wiring portion 181 of the present example may be arranged to be partially overlapped in the top view. Both of the gate runner 46 and the conductive wiring portion 181 extend in the X axis direction; however, the gate runner 46 may extend in the Y axis direction. By providing the interlayer dielectric film 380 between the gate runner 46 and the conductive wiring portion 181, it is possible to enhance a degree of freedom of each wiring inside the interlayer dielectric film 380.

FIG. 4D shows an example of a cross section taken along lines c-c′ shown in FIG. 1 and FIG. 3B. The cross section along the lines c-c′ is a YZ cross section passing between the temperature sensing portion 178 and the gate pad 50.

In FIG. 4D, the gate runner 46 electrically connected to the gate pad 50 is shown. The gate runner 46 is electrically connected to the gate trench portion 40 via the contact hole, and can control the operation of the semiconductor device 100.

When the conductive wiring portion 181 is not provided above the gate runner 46, the first dielectric layer 381 and the second dielectric layer 382 may not be provided above the gate runner 46. An upper surface of the gate runner 46 may be covered with the third dielectric layer 383. The second dielectric layer 382 is provided above the gate runner 46 of the present example. The gate oxide film 384 is provided between the gate runner 46 and the front surface of the semiconductor substrate 10.

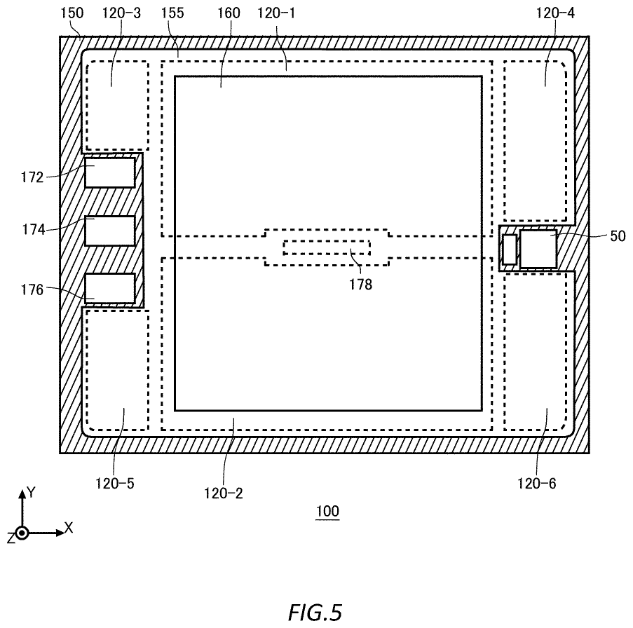

FIG. 5 shows an example of an upper surface of the semiconductor device 100 of the present example. In FIG. 5, hatching is shown in a region where the protective film 150 is provided.

As shown in FIG. 5, in the semiconductor device 100 of the present example, the connection of the temperature sensing portion 178, and the anode pad 174 and the cathode pad 176 is performed inside the interlayer dielectric film 380, and thus the protective film 150 is not provided above the temperature sensing portion 178. This makes it possible to use the single emitter electrode 52 to control the operation of the semiconductor device 100, without the front surface side electrode such as the emitter electrode 52 being separated by the protective film 150.

In the present example, the single emitter electrode 52 is electrically connected to each of the active portion 120-1, the active portion 120-2, the active portion 120-3, the active portion 120-4, the active portion 120-5, and the active portion 120-6 which are provided to be spaced apart. By using the single emitter electrode 52, it is possible to control the operation of the semiconductor device 100, without using a configuration of a wire or the like for connecting the emitter electrodes.

As shown in FIG. 5, in the semiconductor device 100 of the present example, the solder layer 160 and the protective film 150 are separated from each other. This makes it possible to avoid the occurrence of the triple point in the semiconductor device 100, and to prevent the stress concentration.

While the present invention has been described by way of the embodiments, the technical scope of the present invention is not limited to the above-described embodiments. It is apparent to persons skilled in the art that various modifications or improvements can be made to the above-described embodiments. It is also apparent from description of the claims that the embodiments to which such alterations or improvements are made can be included in the technical scope of the present invention.

It should be noted that the operations, procedures, steps, stages, and the like of each processing performed by an apparatus, system, program, and method shown in the claims, specification, or drawings can be realized in any order as long as the order is not indicated by “prior to,” “before,” or the like and as long as the output from a previous processing is not used in a later processing. Even if the operation flow is described using phrases such as “first” or “next” for the sake of convenience in the claims, specification, or drawings, it does not necessarily mean that the process must be performed in this order.

### EXPLANATION OF REFERENCES

10: semiconductor substrate; 12: emitter region; 14: base region; 15: contact region; 16: accumulation region; 18: drift region; 20: buffer region; 21: front surface; 22: collector region; 23: back surface; 24: collector electrode; 25: connection portion; 30: dummy trench portion; 31: extension part; 32: dummy dielectric film; 33: connection part; 34: dummy conductive portion; 38: interlayer dielectric film; 40: gate trench portion; 41: extension part; 42: gate dielectric film; 43: connection part; 44: gate conductive portion; 46: gate runner; 47: metal wiring; 48: gate wiring portion; 49: contact hole; 50: gate pad; 52: emitter electrode; 54: contact hole; 56: contact hole; 57: contact hole; 70: transistor portion; 80: diode portion; 82: cathode region; 100: semiconductor device; 102: edge side; 110: current sensing portion; 120: active portion; 130: well region; 150: protective film; 151: contact region; 152: contact region; 155: plating film; 160: solder layer; 172: current sensing pad; 174: anode pad; 176: cathode pad; 178: temperature sensing portion; 180: first wiring; 181: conductive wiring portion; 182: second wiring; 210: bidirectional diode portion; 220: output comparison diode portion; 380: interlayer dielectric film; 381: first dielectric layer; 382: second dielectric layer; 383: third dielectric layer; 384: gate oxide film.

What is claimed is:

1. A semiconductor device comprising:
an active portion which is provided in a semiconductor substrate;
a temperature sensing portion which has a PN junction provided above the semiconductor substrate;
an interlayer dielectric film provided above the semiconductor substrate; and
a front surface side electrode provided above the interlayer dielectric film, wherein
a contact region between the front surface side electrode and the interlayer dielectric film covers the PN junction, in a top view.

2. The semiconductor device according to claim 1, comprising:
a conductive wiring portion electrically connected to the temperature sensing portion, inside the interlayer dielectric film.

3. The semiconductor device according to claim 2, wherein
the interlayer dielectric film has
a first dielectric layer provided on a lower surface of the conductive wiring portion, and
a second dielectric layer provided on an upper surface of the conductive wiring portion.

4. The semiconductor device according to claim 2, wherein
the conductive wiring portion extends in a predetermined direction, and an entire periphery of a cross section of the conductive wiring portion is covered with the interlayer dielectric film which is non-doped.

5. The semiconductor device according to claim 2, wherein
a cross sectional area of the PN junction is smaller than a cross sectional area of the conductive wiring portion.

6. The semiconductor device according to claim 2, comprising:
a gate runner electrically connected to a gate pad of the active portion, wherein
the gate runner is provided to at least partially overlap the conductive wiring portion, in the top view.

7. The semiconductor device according to claim 1, comprising:
a gate runner electrically connected to a gate pad of the active portion, wherein
the gate runner is provided to at least partially overlap the temperature sensing portion, in the top view.

8. The semiconductor device according to claim 6, wherein
the interlayer dielectric film includes a gate oxide film provided between the gate runner and the semiconductor substrate.

9. The semiconductor device according to claim 6, wherein
the gate runner is provided below the conductive wiring portion with the interlayer dielectric film being sandwiched between the gate runner and the conductive wiring portion.

10. The semiconductor device according to claim 6, wherein
the conductive wiring portion has
a first wiring which is connected to one end of the temperature sensing portion, and which extends in a predetermined direction inside the interlayer dielectric film; and
a second wiring which is connected to another end of the temperature sensing portion, and which extends in a predetermined direction inside the interlayer dielectric film.

11. The semiconductor device according to claim 6, wherein
the gate runner is made of polysilicon.

12. The semiconductor device according to claim 3, wherein
the second dielectric layer covers an upper surface of the temperature sensing portion.

13. The semiconductor device according to claim 2, wherein
the conductive wiring portion is made of polysilicon.

14. The semiconductor device according to claim 3, wherein
the conductive wiring portion is made of polysilicon.

15. The semiconductor device according to claim 4, wherein
the conductive wiring portion is made of polysilicon.

16. The semiconductor device according to claim 2, wherein
the conductive wiring portion is made of a metal material.

17. The semiconductor device according to claim 3, wherein
the conductive wiring portion is made of a metal material.

18. The semiconductor device according to claim 1, comprising:
a plating film provided on an upper surface of the front surface side electrode, wherein
a contact region between the plating film and the front surface side electrode covers the temperature sensing portion, in the top view.

19. The semiconductor device according to claim 18, comprising:
a solder layer which is provided on an upper surface of the plating film, and which covers an upper side of the temperature sensing portion.

20. The semiconductor device according to claim 19, comprising:
a protective film provided to be spaced apart from the solder layer, above the front surface side electrode.
